(19) United States
(12) Patent Application Publication
(10) Pub. No.: US 2025/0276580 A1
(43) Pub. Date: Sep. 4, 2025

(54) SCREEN ADJUSTER FOR A MOTOR VEHICLE

(71) Applicant: Brose Fahrzeugteile SE & Co. Kommanditgesellschaft, Coburg, Coburg (DE)

(72) Inventors: Heike JAGUSCH, Coburg (DE); Raymond JAGUSCH, Coburg (DE); Kiung JU, Hwaseong-si (KR); Sergej KOSTIN, Coburg (DE); Gregor KROENER, Bischberg (DE)

(73) Assignee: Brose Fahrzeugteile SE & Co. Kommanditgesellschaft, Coburg, Coburg (DE)

(21) Appl. No.: 19/068,983

(22) Filed: Mar. 3, 2025

(30) Foreign Application Priority Data
Mar. 1, 2024 (DE) 10 2024 201 965.8

(51) Int. Cl. B60K 35/53; B60K 35/22; H05K 5/02

(52) U.S. Cl. CPC B60K 35/53; B60K 35/22; H05K 5/0217; B60K 2360/816

(57) ABSTRACT

A screen adjustment device for a motor vehicle is provided that comprises a screen reversibly movable between a parking position and at least one operating position and/or screen support for mounting such a screen. At least one electromotive drive unit generates an actuating force which causes an adjustment of the screen and/or screen support. A positioning mechanism guides the screen and/or screen support between the parking position and at least one operating position and transmits the actuating force. The positioning mechanism having at least one spindle drive with a threaded spindle and with a spindle nut arranged on it. The spindle drive being coupled to the screen and/or to the screen support and to the drive unit.

This nonprovisional application claims priority under 35 U.S.C. § 119 (a) to German Patent Application No. 10 2024 201 965.8, which was filed in Germany on Mar. 1, 2024, and which is herein incorporated by reference.

### BACKGROUND OF THE INVENTION

### Field of the Invention

The invention relates to a screen adjustment device for a motor vehicle, in particular for a vehicle interior.

### Description of the Background Art

In modern motor vehicles, a screen (dash display) is often provided in the area of the dashboard or the center console, which serves as the output interface of an on-board computer to display a wide range of environmental and operating variables, such as the outside temperature, fuel consumption, etc. In addition or alternatively, such a screen often serves as an output device for a navigation system, car radio or similar. If a touch-sensitive screen is used or if separate controls are assigned to a display that is not touch-sensitive in itself, such a screen can also serve as an input interface for the on-board computer, the navigation system, or the car radio.

Such screens are preferably installed in the dashboard or in the center console so as to swivel or tilt, so that the screen can be swiveled or tilted sideways towards both the driver and the front passenger. This allows for increased flexibility and improved visibility for both occupants, which significantly increases operating comfort and safety while driving as compared to fixed screens.

Swiveling screens are often adjustable by means of a screen adjustment device (screen adjuster) in such a way that they are swiveled from a resting or parking position in which they are adjacent to the dashboard. With such a swivel movement, it is necessary for the screen to be moved at least partially out of the dashboard, i.e., in the direction of the vehicle interior, otherwise part or a section of the screen is swiveled into the interior of the dashboard, thus adversely affecting the full visibility and accessibility of the screen. It is therefore necessary to move motor vehicle screens along an, often complex, adjustment travel between the parking position and an operating position-which is swiveled in the vehicle interior. To move to the operating position, the screen is usually pushed out of the dashboard in an essentially horizontal direction and then, or simultaneously, tilted or swiveled into an operating position inclined sideways towards the driver or front passenger, in which the screen is clearly visible to the vehicle occupant.

For example, screen adjustment devices are conceivable in which two permanently mounted spindle drives, or spindle adjusters, and an additional lever are used to move and rotate/swivel the screen. The screen is guided in a groove on the back by means of a pin for stabilization. Disadvantageously, additional installation space and additional components are required to guide the pin, which limits the flexibility of the screen adjustment device due to the limited installation space in the dashboard.

### SUMMARY OF THE INVENTION

It is therefore an object of the invention to provide a particularly suitable screen adjustment device for a motor vehicle. In particular, the aim is to specify a screen adjustment device with as few components and as little installation space as possible.

The screen adjustment device according to an example of the invention comprises a screen (display, monitor) and/or a screen support (screen holder) on which the screen can be held. The conjunction “and/or” is to be understood here and in the following in such a way that the features linked by means of this conjunction can be formed both together and as alternatives to each other.

The screen or screen support can be moved reversibly between a parking position and at least one operating position. In order to generate an actuating force for adjusting the screen or screen support, the screen adjustment device comprises at least one electromotive drive unit.

Furthermore, the screen adjustment device comprises a positioning mechanism that serves to guide the screen and/or screen support along an adjustment travel between the parking position and the at least one operating position and to transmit the actuating force.

If the screen support is not provided, the positioning mechanism directly engages the screen, so that the screen is a necessary part of the screen adjustment device. Otherwise, the positioning mechanism engages the screen support, to which the screen is attached. In the latter case, in a convenient design, the screen adjustment device is fully functional even without a screen, so that the screen is not a necessary part of the screen adjustment device. However, it is also conceivable that the positioning mechanism is connected to the screen as well as to a screen support holding or supporting it.

In any case, the positioning mechanism can have at least one spindle drive. The spindle drive comprises at least one threaded spindle with a spindle nut coupled to it.

To adjust the screen or screen support, the spindle drive is coupled or connected to the screen and/or screen support on the one hand and to the at least one drive unit on the other. This means that a particularly suitable screen adjustment device has been implemented.

The positioning mechanism can have a rail arrangement oriented along the linear adjustment range, in particular, with a bottom rail (guide rail) for coupling to the screen and/or screen holder and an top rail (guide slide) for coupling to the drive unit that is seated in the bottom rail in a form-fitting and relatively movable manner. In other words, a linear drive is provided to adjust the screen and/or the screen holder.

The threaded spindle is fixed to the bottom rail, with the spindle nut being connected to the top rail in terms of drive technology. For example, the drive unit may be directly or indirectly connected to the top rail. For example, a joining or mounting plate that can be connected to the top rail is provided, to which the drive unit and the screen and/or the screen holder are attached.

Preferably, a rail arrangement is used as described in the applicant's German application 10 2022 207 168.9, which corresponds to PCT/EP2022/082230, which is incorporated herein by reference. Its disclosed content, in particular its claims (with related explanations), are hereby expressly included in the present application, wherein the statements regarding the longitudinal seat adjustment are transferable mutatis mutandis to the screen adjustment. The content of this application is incorporated by reference as an integral part of the present application. Reference is made specifically to the feature that the top rail has additional track rollers arranged at an angle, which are spring-loaded on obliquely oriented side walls of the bottom rail.

The top rail can be arranged in a fixed position, wherein the bottom rail is displaced relative to this by the spindle drive. The bottom rail is connected to the screen and/or the screen support, for example, by mounting flanges, wherein the top rail is fixed to a frame of the dashboard or center console, for example, via a mounting plate.

This ensures play-free guidance along the adjustment travel formed by the bottom rail. Due to the freedom from play, fluttering or rattling noises are reliably avoided when adjusting the screen.

The linear drive, for example, is designed according to the modular principle, so that many identical parts can be used for the different applications (screen adjustment, seat adjustment, . . . ). The variance arises only due to the “bottom rail” length and specific connection parts.

The screen adjustment device according to the invention can be designed with a laterally swiveling screen and/or screen holder.

The drive unit can be coupled to the spindle nut and the threaded spindle to the screen and/or to the screen support. In other words, the spindle nut is driven by the drive unit in order to adjust the screen and/or screen support, with the threaded spindle coupled to the screen and/or screen support and retracted and extended relative to the spindle nut.

The threaded spindle can be directly connected to the screen and/or to the screen support at the end in an articulated or movable manner. The threaded spindle can be connected to the screen and/or the screen support by means of a swivel joint, so that the screen and/or the screen support can be swiveled or tilted to the side.

In a practical design, the positioning mechanism can have a longitudinal adjustment unit with a bracket and with at least one motor cage fixed to it, wherein the at least one drive unit is rotatable in the motor cage. The motor cage is the stationary bearing for the spindle nut driven by the drive unit. The drive unit being rotatable on the motor cage makes it possible for the threaded spindle to be swiveled relative to the bracket or motor cage without affecting the drive or the actuating force.

The positioning mechanism or the longitudinal adjustment unit can have two hinged threaded spindles coupled to the screen and/or the screen support and two motor cages fixed to the bracket. In each of the motor cages, a rotatable drive unit is mounted, which is coupled with a spindle nut for adjusting one of the threaded spindles in terms of drive technology. The spindle nuts are also located in the motor cages.

In this design, the screen and/or the screen support can be mounted directly on two threaded spindles, which are driven by two swiveling spindle adjusters. The more direct drive of the screen and/or screen support by the spindle drives reduces the number of components (no additional coupling). As a result, the production costs and the installation space required for installation are be reduced. To be more precise, a larger adjustment angle for the screen and/or the screen support can be realized in the same installation space. The reduced number of components results in less susceptibility to play and sensitivity to vehicle vibrations.

The bracket can be directly or indirectly hinged to the screen and/or to the screen support. Preferably, the bracket is pivotally connected to the screen and/or the screen support via a swivel joint. This ensures stable and reliable guidance of the screen and/or screen support.

For example, the bracket of the longitudinal adjustment unit between the spindle adjusters can be designed as a rail guide. For example, the rail guide can be designed in the manner of the applicant's German application of Jul. 13, 2022. The rail guide has a stationary or fixed bottom rail, and a top rail guided on it, wherein the top rail is pivotally connected to the screen and/or the screen support at the end by a swivel joint. The stability of the screen and/or the screen support, especially in the extended position, can be increased with the hinged top rail.

A guide groove can be inserted into the bracket, in which a guide element connected to the screen and/or to the screen support is guided in a movable manner. The guide groove as a guide track stabilizes the screen and/or the screen support when these are extended. The risk that the guide element takes a wrong path in the guide groove is virtually eliminated.

In an expedient design, the guide groove can have an essentially V-shaped course in the bracket. The two V-legs correspond to the two travel or adjustment ranges for swiveling in the direction of the driver or passenger, wherein the V-base (i.e., the point of contact of the two V-legs) corresponds to the retracted resting position.

The screen and/or the screen support can be moved between the parking position and two operating positions by means of the positioning mechanism, wherein the two threaded rods are moved different distances in the operating positions.

Depending on the ratio of the travel or adjustment range of the threaded spindles, the screen and/or screen support will move away from the bracket and swivel left or right at the same time. When installed in a dashboard, the screen and/or the screen support thus moves out of the dashboard and at the same time swivels towards the driver or passenger. In other words, the screen and/or the screen support with the spindles move at least partially out of the dashboard, so that the visibility of the screen is not impaired when swiveling. An additional guide (e.g., pin in groove) is not necessary for the movement of the screen and/or screen support but may be provided for additional stabilization. For swiveling, for example, one of the threaded spindles is extended only half as far as the other threaded spindle.

In the event of a power failure, it is desirable that an extended or swiveled screen and/or screen support can be manually moved back to the resting position (parking position) or into the dashboard. For this purpose, it is provided in a suitable further development that the at least one drive unit is designed by means of gearing and transmission in such a way that it can be driven backwards in the direction of the parking position. In emergency operation, manual retraction is thus implemented via a non-self-locking drive unit.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a screen adjustment device in an operating position in a perspective representation,

FIG. 2 shows the screen adjustment device in a parking position in a perspective representation,

FIG. 3 shows an adjustment unit of the screen adjustment device with mounting flanges in a perspective representation,

FIG. 4 shows the adjustment unit without the mounting flanges in a perspective representation,

FIG. 5 shows the adjustment unit in a disassembled state in a perspective exploded representation,

FIG. 6 shows the adjustment unit in a side view,

FIG. 7 shows a screen adjustment device in accordance with an example in a parking position in a plan view,

FIG. 8 shows the screen adjustment device in accordance with the example in the parking position in a perspective representation,

FIG. 9 shows the screen adjustment device in accordance with the example in an operating position in a plan view,

FIG. 10 shows the screen adjustment device in accordance with the example in the operating position in a perspective representation,

FIG. 11 shows a screen adjustment device in accordance with an example in a parking position in a plan view, and

FIG. 12 shows the screen adjustment device in accordance with the example in an operating position in a plan view.

### DETAILED DESCRIPTION

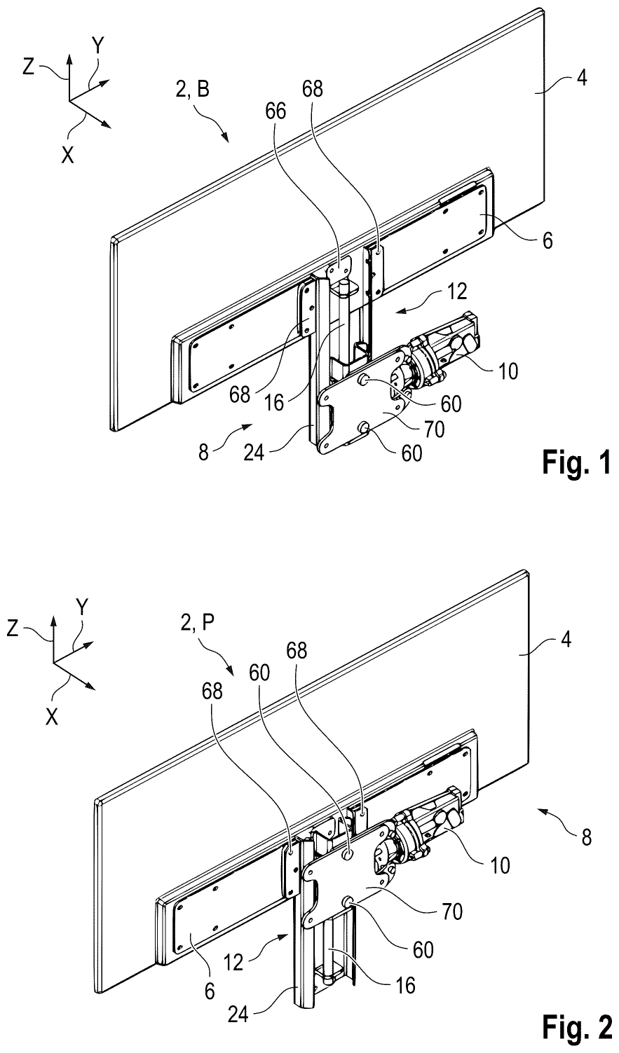

The screen adjustment device 2 shown in FIG. 1 is intended in particular for installation in a dashboard or in a center console of a motor vehicle. In particular, the screen adjustment device 2 is arranged approximately in the middle between a driver's seat and a front passenger seat.

In the following, information regarding spatial directions is also given, in particular in a coordinate system of the motor vehicle (vehicle coordinate system) with regard to an exemplary installation situation of the screen adjustment device 2 in a dashboard. The abscissa axis (X-axis, X-direction) is oriented along the longitudinal direction of the vehicle (direction of travel) and the ordinate axis (Y-axis, Y-direction) along the transverse direction of the vehicle, and the applicate axis (Z-axis, Z-direction) is oriented along the height of the vehicle.

The screen adjustment device 2, for example, has a screen 4 permanently connected to it as a vehicle display. Instead of a screen 4 permanently connected to the screen adjustment device 2, the screen adjustment device 2 may also comprise a screen support 6 to which a screen 4 can be attached retroactively. In the latter case, the screen adjustment device 2 is fully functional even without a screen 4. It is also conceivable that the screen adjustment device 2 is connected both to a screen support 6 and to a screen 4 held by it.

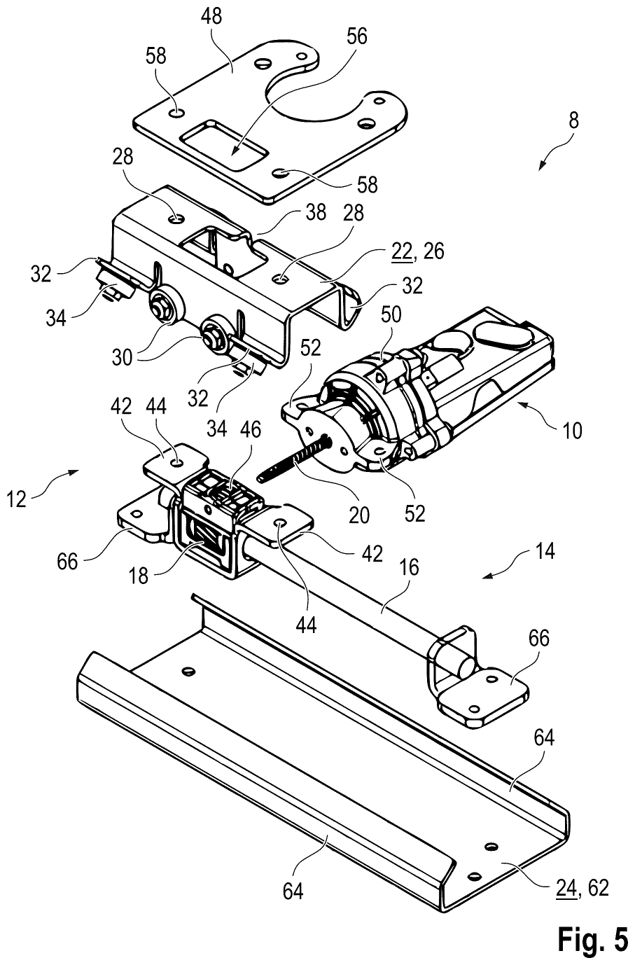

In the example of FIGS. 1 to 6, the screen adjustment device 2 has a screen support 6 and a screen 4 mounted on it. The screen support 6—and thus the screen 4—can be moved reversibly relative to the dashboard by means of an adjustment unit 8. When the adjustment unit 8 is activated, the screen support 6 or the screen 4 is moved between a parking position P (FIG. 2) recessed in the dashboard and an extended operating position B (FIG. 1).

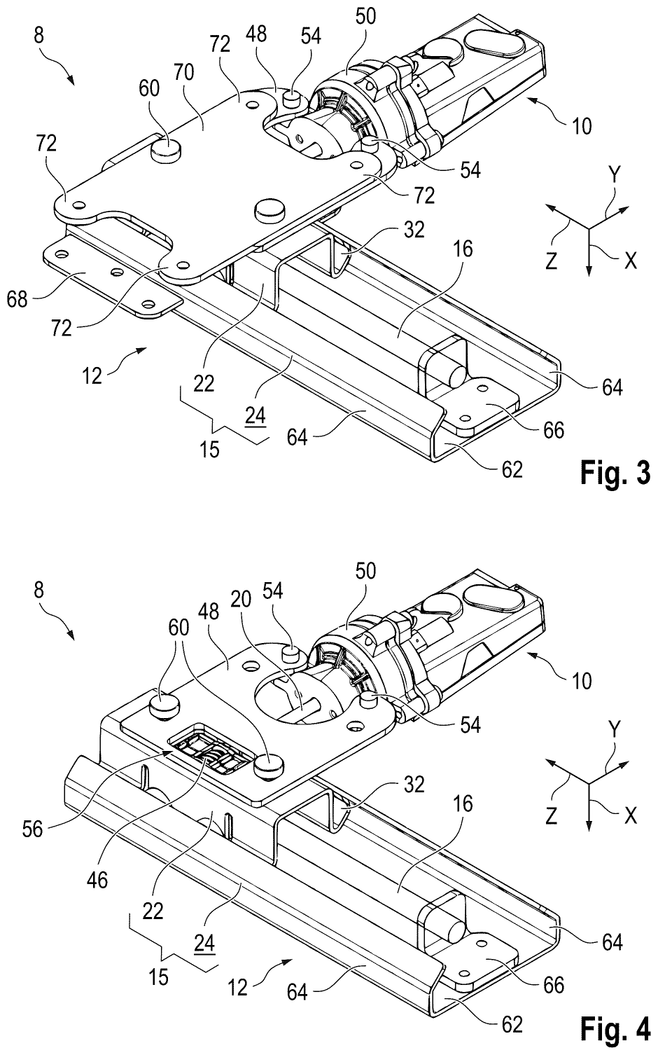

The adjustment unit 8, which is explained in more detail below on the basis of FIGS. 3 to 6, has an electromotive drive unit 10 and a positioning mechanism 12.

The positioning mechanism 12 has a spindle drive 14 and a rail arrangement 15.

The spindle drive 14 comprises a threaded spindle 16 and a spindle nut 18 moveably guided thereon. The spindle nut 18 is in a drive coupling with a drive shaft 20 of the drive unit 10. When the drive unit 10 is actuated, the spindle nut 18 is driven, and is thus adjusted along the threaded spindle 16.

The rail arrangement 16 has a top rail 22 and a bottom rail 24 guided on it so that it can be moved.

The top rail 22 is designed as a guide carriage with a roughly U-shaped carriage body 26. The horizontal U-leg has two mounting openings 28 for coupling with the spindle nut 18 and with the drive unit 10.

The carriage body 26 has an essentially three-part structure along the longitudinal direction of the body. In the middle area of the carriage body 26, four load-bearing load rollers 30 are arranged, which are arranged in pairs and rotatable on one of the vertical U-legs opposite each other. In the outer sections of the carriage body 26, the vertical U-legs are bent outwards and upwards as spring tabs 32 in the direction of the horizontal U-leg. A rotatable track roller 34 is attached to each of the spring tabs 32, arranged on the free-end side. The spring tabs 32 are preferably flexible or resilient.

In the horizontal U-leg, between the mounting openings 28, a window-like recess 36 is incorporated for the spindle nut 18, wherein the recess 36 is coupled with a slot 38 extending in sections over the vertical U-leg on the drive side.

The spindle nut 18 is pivotably or rotatably mounted in a cage-like bracket 40. The bracket 40 is essentially U-shaped, with the free ends of the vertical U-legs bent outwards at right angles as mounting tabs 42. The mounting tabs 42 each have a mounting opening 44.

Above the spindle nut 18, a drive element 46 is arranged in the bracket 40. The drive element 46 has, for example, a worm shaft meshing with the external thread of the threaded nut 18, which is connected to the drive shaft 20 in the assembled state.

For assembly, the bracket 40 is inserted from below into the carriage body 26 of the top rail 22, so that the drive element 44 sits in the recess 36, and so that the mounting openings 44 are arranged in alignment with the mounting openings 28. Subsequently, the drive shaft 20 is coupled laterally through the slot 38 to the drive element 46.

The top rail 22 can be permanently connected to the drive unit 10 via a mounting plate 48. For this purpose, a drive housing 50 of the drive unit 10 has side-molded mounting flanges 52, which can be fixed to the mounting plate 48 by fasteners 54.

The mounting plate 48 also has a window-like recess 56 and two mounting openings 58. Recess 56 is aligned with recess 36, with mounting openings 58 aligned with mounting openings 28 and 44. The top rail 22, the bracket 40 and the mounting plate 48 are firmly connected by two fasteners 60 that penetrate the mounting openings 28, 44, 58.

The approximately U-shaped bottom rail 24 has a rail floor 62 as a horizontal U-leg and two side walls 64 as vertical U-legs. The free ends of the side walls 64 are angled diagonally inwards. The threaded spindle 16 is non-rotatably attached to the rail floor 62 of the bottom rail 24 by means of two fastening brackets 66.

The bottom rail 24 is coupled to the screen support 6 via two mounting end plates 68. The mounting end plates 68 are arranged vertically to the outside on the end of the rail on the side walls 64.

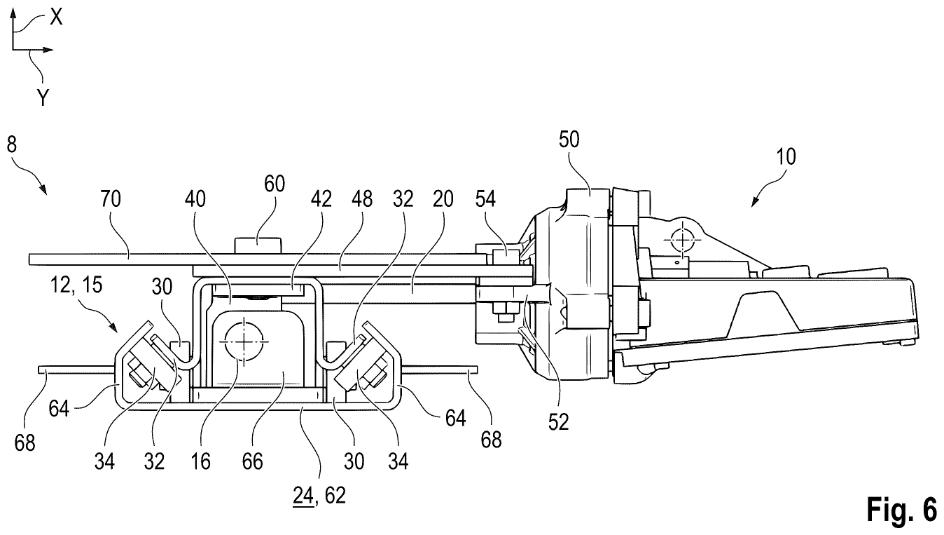

The top rail 22 and the drive unit 10 are mounted stationary or fixed when installed. For this purpose, a mounting plate 70 with four mounting tabs 72 is provided, which is firmly connected to the top rail 22, the bracket 40 and the mounting plate 48 via fasteners 60 (FIG. 3, FIG. 6).

When assembled, the top rail 22 and bottom rail 24 are oriented along the vehicle height direction Z. As can be seen in particular in FIG. 6, the top rail 22 is seated in a form-fitting manner in the bottom rail 24. The positive fit is oriented along a vertical rail height direction (i.e., along the vehicle's longitudinal direction X) and along a rail transverse direction (i.e., along the vehicle's transverse direction Y) of the rail arrangement 15. The load rollers 30 of the top rail 22 sit on the rail floor 62, wherein the diagonally oriented track rollers 34 of the spring tabs 32 are supported as running surfaces on the diagonally inwardly directed sections of the side walls 64.

By supporting the top rail 22 at the same time by means of the load rollers 30 and the track rollers 34 on the bottom rail 24, a play-free guidance along the adjustment range formed by the bottom rail 24 is realized. Due to the freedom from play, fluttering or rattling noises when adjusting the screen 4 are reliably avoided.

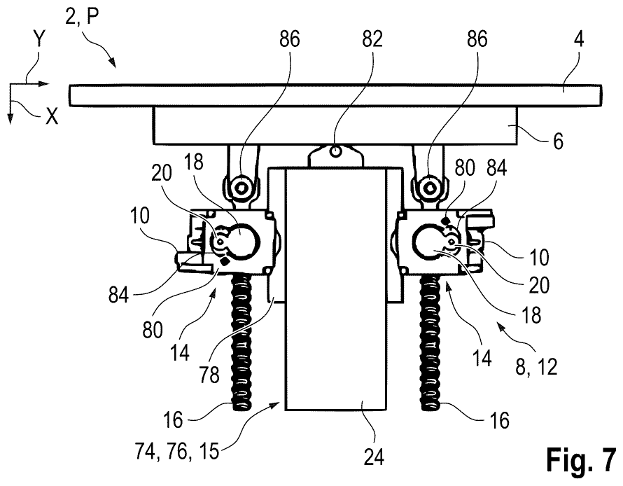

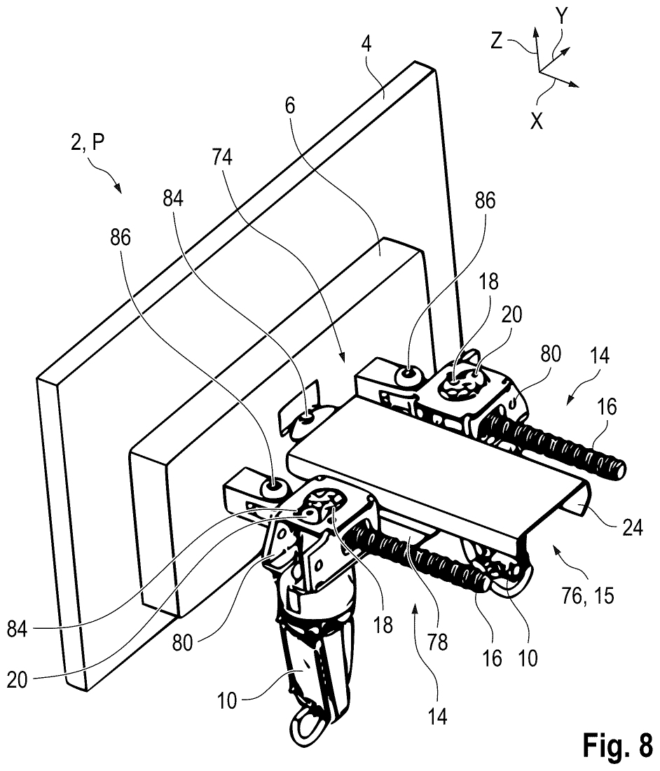

A second example of the screen adjustment device 2 is explained in more detail below using FIGS. 7 to 10. In this example, the screen 4 and/or the screen support 6 can be swiveled sideways by means of the screen adjustment device 2.

The screen adjustment device 2 is adjustable between a parking position P and two sideways swiveling operating positions B1, B2, wherein one operating position is swiveled to the driver's seat and the other operating position to the front passenger seat. In the figures, only one operating position is depicted, the other is essentially the result of a reflection. In the parking position P, the screen 4 is arranged parallel and preferably visually aligned with a visible area of the dashboard.

In this example, the adjustment unit 8 has two drive units 10, wherein the positioning mechanism 12 is designed with two spindle drives 14 and with a longitudinal adjustment unit 74 arranged in between.

The longitudinal adjustment unit 74 has a bracket 76. The bracket 76 comprises a stationary or fixed mounting plate 78 on which two fixed motor cages 80 are arranged. The motor cages 80 are designed for the support of the two drive units 10 as well as for the stationary and rotatable bearing of the spindle nuts 18.

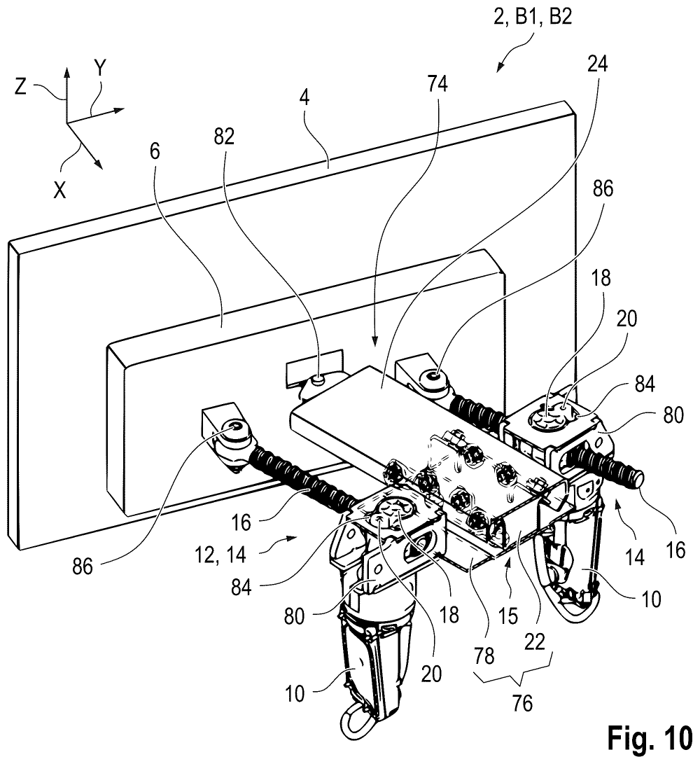

As can be seen in particular in the illustration of FIG. 10, the longitudinal adjustment unit 74 or the bracket 76 has a rail arrangement 15, wherein a top rail 22 is fixed on the mounting plate 78, and a bottom rail 24, which is arranged on it in a movable manner, is hinged to the screen support 6 by means of a swivel joint 82. The linear rail guidance stabilizes the extension of the screen 4 or screen support 6 into the vehicle interior, with the swivel joint 82 forming the swivel axis for the swivel movement towards the driver's seat or front passenger seat.

The drive units 10 are mounted on the respective motor cages 80 in a rotatable manner. The drive units 10 can thus rotate along a rotary or swivel axis oriented essentially parallel to the drive shaft 20 relative to the fixed motor cage 80. For this purpose, the motor cage 80 has a recess in the shape of a kidney or bean as a guide contour 84 for the drive shaft 20.

The threaded spindles 16 are each coupled to the screen support 6 via a spindle-end-side swivel joint 86. The threaded spindles 16 can be swiveled via the swivel joints 86 relative to the screen support 6. However, along the spindle longitudinal direction, the threaded spindles 16 are arranged in a non-rotatable manner.

When adjusting the screen adjustment device 2 from the parking position P to one of the operating positions B1, B2, the drive units 10 are activated, thus driving the spindle nuts 18. This moves the threaded spindles 16 along the X-direction, thereby moving the bottom rail 24 along the top rail 22 so that the screen 4 or the screen support 6 is moved out from the dashboard.

In a conceivable design, one of the drive units 10 is then stopped, while the other drive unit 10 continues to drive the assigned spindle nut 18. This continues to move this side further along the X direction. In an example, however, both drive units 10 are operated at different adjustment speeds, and essentially arrive at their end positions at the same time.

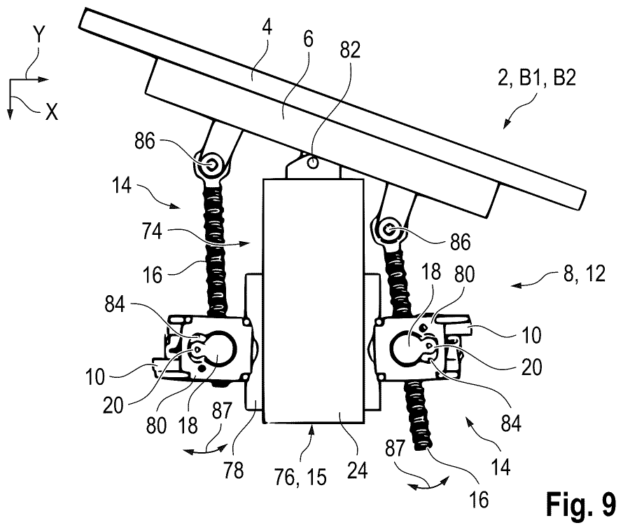

By means of the swivel joints 86 and 82, the screen support 6 and the screen 4, respectively, are swiveled laterally around the swivel axis formed by the swivel joint 82. As a result, the swivel joint 86 of the non-driven or slower spindle drive 14 is swiveled inwards, wherein the articulated bearing tilts or swivels the threaded spindle 16 parallel to the Z-direction (cf. e.g., FIG. 9). The swivel of the threaded spindle 16 is limited by the rotation of the stationary or slower drive unit 10, which is limited in the guide contour 84. The drive shaft 20—and thus the drive unit 10—is swiveled along the guide contour 84 when the threaded spindle 16 is moved due to the rotatable drive unit. As a result, the threaded spindle 16 of the non-active or slower spindle drive 14 is swiveled relative to the bracket 76 or the motor cage 80 without affecting the drive unit 10 or the actuating force.

When extending, the drive shafts 20 or the gearbox housing of the drive unit 10 thus rotate in the motor cage 80, so that a changing distance of the spindle eye forming the swivel joint 86 to the vehicle center due to the swiveling movement is compensated. The swivel movement indicated in FIG. 9 with a double arrow 87 is not limited, and results from the adjustment movement of the screen 4.

In a suitable dimensioning, it is necessary, for example, for the adjustment or movement from the parking position P to the operating position B1, that one drive unit 10 has an adjustment range of 100 mm (millimeters) and the other drive unit 10 has an adjustment range of 50 mm. With a target travel time of 4 s (seconds), the first drive unit travels at an adjustment speed of 25 mm/s (millimeters per second), and the other drive unit at 12.5 mm/s. This makes it look as if the screen 4 only tilts out of the dashboard by the edge of the screen in the vehicle interior (cf. e.g., illustrations of FIG. 7 and FIG. 9).

The advantage of the swivel adjustment of the example in FIG. 7 to FIG. 10 is that a desired adjustment angle can be swiveled to a fixed adjustment angle (e.g.,) 20°. Thus, for example, any desired adjustment angle (e.g., 10°, 15°, . . . ) can be set by appropriate software and/or control of the electromotive drive units 10. Furthermore, it is possible to easily adapt to different screen dimensions (display sizes) without having to change parts of the screen adjustment device 2 geometrically.

A further advantage is that the screen adjustment device 2 in FIG. 7 to FIG. 10 allows for direct swiveling between the operating positions B1, B2 by one drive unit 10 running forward and the other drive unit 10 backwards. This eliminates the need to temporarily return to the parking position P.

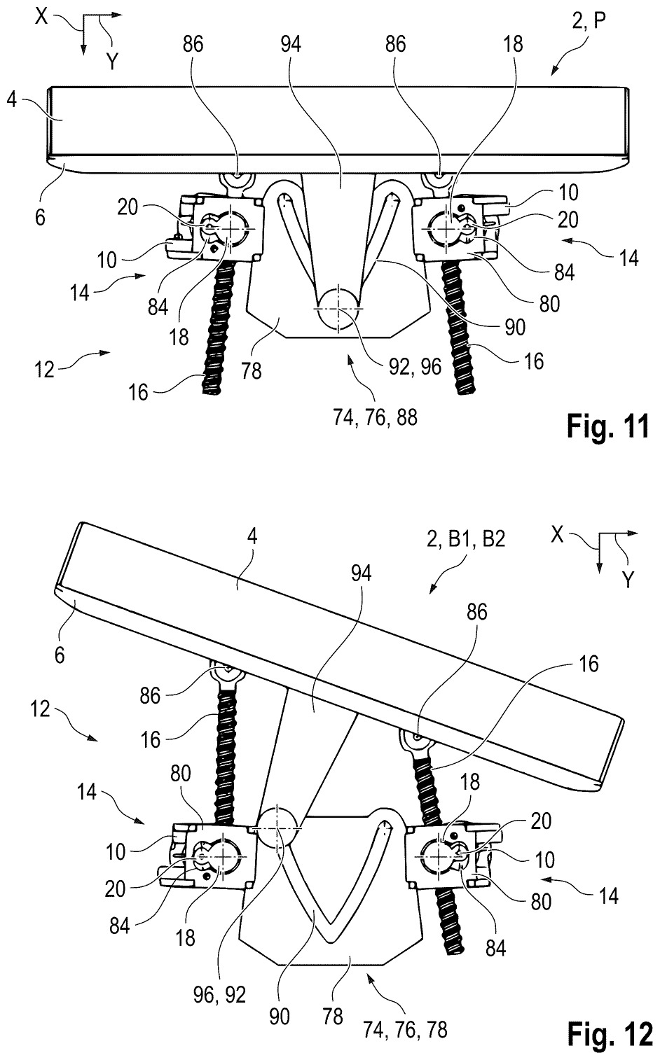

A third example of the screen adjustment device 2 is explained in more detail below on the basis of FIG. 11 and FIG. 12. This example is essentially the same as the example in FIGS. 7 to 10 described above, in which the rail arrangement 15 of the longitudinal adjustment unit 74 is replaced by a groove guide 88.

The groove guide 88 has a guide groove 90 as a guide track for a guide element 92 designed as a (guide) pin. The guide groove 90 is designed as a V-shaped recess of the mounting plate 78 in the XY-plane, wherein the V-legs are slightly curved or bent outwards. The guide element 92 sits in the guide groove 90 in a form-fitting and movable manner and is firmly connected to the back of the screen 4 or the screen support 6 via a bracket 94.

The guide element 92, which can be rotated in the guide groove 90, also realizes a swivel joint 96 for the lateral swiveling of the screen 4 and/or the screen support to the operating position B1, B2 (FIG. 12).

In FIG. 11, the screen adjustment device 2 is located in the parking position P. The guide element 92 is located at the V-base of the V-shaped guide groove 90, which corresponds to the farthest point of the guide groove 90 to the screen 4 and/or screen support 6.

In order to move the screen adjustment device 2 from the parking position P to the operating position B1, B2 (or back), both drive units 10 are preferably operated at different adjustment speeds.

Alternatively, the drive unit 10 is activated first, which is located on the side on which the spindle drive 14 is further extended. This ensures that the guide element 92 slides into the V-leg of the guide groove 90 assigned to the desired operating position B1, B2. In particular, the guide element 92 is pulled into the V-leg by the bracket 96 when the drive element 10 drives the spindle drive 14 and adjusts the threaded spindle 16.

The second drive unit 10 is then also activated until the screen support 6 or screen 4 is extended sufficiently far out of the dashboard. The first drive unit 10 adjusts the corresponding spindle drive 14 until the guide element 92 has reached the free end of the V-leg of the guide groove 90.

During the adjustment, the screen 4 and/or screen support 6 tilts or swivels by rotating the guide element 92 around the axis of rotation formed by the guide element 92 or the swivel joint 96. The curvature or arch of the V-leg of the guide groove 90 is dimensioned accordingly so that no unnecessary tension or stress acts on the guide element 92.

The example of the guide groove 90 as a V-contour with a curved guide track is only one conceivable possibility. The type of guide track or guide groove 90 depends on how the screen 4 should rotate when it is moved out of the dashboard. It is therefore also possible to make the guide track straight (linear). In terms of its geometry, the guide groove 90 is preferably adapted to the desired adjustment kinematics and, above all, to the screen size.

The claimed invention is not limited to the examples described above. Rather, other variants of the invention can also be derived by the skilled person within the framework of the disclosed claims without departing from the subject-matter of the claimed invention. In particular, all the individual features described in connection with the various examples can also be combined in other ways within the framework of the disclosed claims without departing from the subject-matter of the claimed invention.

The motor speeds of the drive units 10 are controlled accordingly to ensure that the screen swivels in and out smoothly and comfortably. Preferably, the drive units 10 have BLDC electric motors.

The screen adjustment devices 2 in FIGS. 1 to 12 are preferably designed in such a way that, in the event of a power failure, an extended or swiveled screen 4 and/or screen support 6 can be manually moved back to the resting position (parking position P) or into the dashboard. For this purpose, it is provided that each drive unit 10 and each spindle drive 14 are designed with a gearing and transmission in such a way that they can be driven backwards in the direction of the parking position P. In emergency operation, manual retraction is thus implemented via a non-self-locking drive unit 10 or a non-self-locking positioning mechanism 12.

In the case of the screen adjustment devices 2 of the examples described above, in each case one screen 4 and one screen support 6 are provided. However, the screen adjustment devices 2 may also be designed with only a screen 4 or with only a screen support 6.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A screen adjustment device for a motor vehicle, the screen adjustment device comprising:
a screen and/or a screen support for supporting the screen adapted to be reversibly moved between a parking position and at least one operating position;
at least one electromotive drive unit to generate an actuating force which causes the screen and/or screen support to be adjusted; and
a positioning mechanism for guiding the screen and/or screen support between the parking position and the at least one operating position as well as for transmitting the actuating force,
wherein the positioning mechanism has at least one spindle drive with a threaded spindle and with a spindle nut arranged on it, and
wherein the spindle drive is coupled with the screen and/or with the screen support and with the drive unit (10).

2. The screen adjustment device according to claim 1, wherein the drive unit is coupled to the spindle nut and the threaded spindle to the screen and/or to the screen support.

3. The screen adjustment device according to claim 2, wherein the threaded spindle is directly connected to the screen and/or to the screen support at an end.

4. The screen adjustment device according to claim 2, wherein the positioning mechanism has a longitudinal adjustment unit with a bracket and with at least one motor cage fixed thereto, and wherein the at least one drive unit is rotatably mounted in the motor cage.

5. The screen adjustment device according to claim 4, wherein the positioning mechanism has two threaded spindles articulated to the screen and/or the screen support and two motor cages arranged permanently on the bracket, wherein, in each of the motor cages, a drive unit is rotatably mounted, which is coupled in terms of drive technology with a spindle nut for adjusting each of the threaded spindles.

6. The screen adjustment device according to claim 4, wherein the bracket is articulated to the screen and/or to the screen support.

7. The screen adjustment device according to claim 6, wherein a guide groove is incorporated in the bracket in which a guide element connected to the screen and/or to the screen support is guided in a movable manner.

8. The screen adjustment device according to claim 7, wherein the guide groove has an essentially V-shaped course in the bracket.

9. The screen adjustment device according to claim 5, wherein the screen and/or the screen support are adapted to be moved by the positioning mechanism between the parking position and two operating positions, and wherein the two threaded rods are moved different distances in the operating positions.

10. The screen adjustment device according to claim 2, wherein at least one drive unit is designed such that it is adapted to be driven backwards in a direction of the parking position via a gearing and transmission.
